(19) United States
(12) Patent Application Publication
(10) Pub. No.: US 2010/0037953 A1
(43) Pub. Date: Feb. 18, 2010

(54) Device for focusing reflected light from a parabolic trough reflector onto focal points in a longitudinal direction

(76) Inventor: Jinchun Xie, Redwood City, CA (US)

Correspondence Address: SCHEIN & CAI LLP;James Cai, 111 W. ST. JOHN ST., SUITE 1250, SAN JOSE, CA, 95113, US

(21) Appl. No.: 12/378,712

(22) Filed: Feb. 17, 2009

Related U.S. Application Data
(60) Provisional application No. 61/065,782, filed on Feb. 15, 2008.

(51) Int. Cl. H01L 31/00; F24J 2/12

(52) U.S. Cl. 136/259; 126/686; 126/683; 126/694

(57) ABSTRACT

A device for focusing reflected light from a trough reflector onto a focal point in a longitudinal direction is disclosed. The device includes a focusing device disposed on a focal line of the trough reflector, the focusing device forming a longitudinal focal point with high light intensity in overlapping relationship to a transverse focus point provided by the trough reflector.

### CROSS REFERENCE TO RELATED APPLICATIONS

This application claims priority from provisional application Ser. No. 61/065,782 filed on Feb. 15, 2008 entitled “Method and Device to Refocus Reflected Light From a Trough Solar Reflector Into Focal Spots in Longitudinal Direction” and from provisional application Ser. No. 61/066,586 filed on Feb. 22, 2008 entitled “Method and Device to Focus the Reflected Light From a Trough Solar Reflector into Focal Spots in Longitudinal Direction”, the entire specifications of which are herein incorporated.

### BACKGROUND OF THE INVENTION

The present invention relates generally to trough solar reflectors and more particularly to a device for focusing reflected light from a trough solar reflector onto focal points in a longitudinal direction.

A prior art parabolic trough reflector 298 is shown in FIG. 2. A Cartesian coordinate system 221 is drawn on the parabolic trough reflector 298 to indicate axes and directions with the origin at the vertex of the parabolic curve. The trough reflector 298 rotates along the z-axis or a line parallel to the z-axis to track the sun 100 moving across the sky. The reflected light 111 is focused on a focal line 211 disposed above the vertex. In the tracking position, the sun 100 is always in the yz plane. When the sun light is also perpendicular to the z-axis, that is, in the xy or transverse plane, the reflected light 111 is focused into a point. In the yz or longitudinal plane, the reflected light 111 is unfocused in parallel. In most cases, the parabolic trough reflector 298 only rotates around one axis and its normal direction (y) has an angle θ with reference to the rays 101 of the sun 100. Still, the reflected light 111 is focused on a line. From a point on the focal line 211, an arc area is traced back for light rays from the trough. This area comprises a parabolic focusing plane 162 and is delineated out by an arc (shown as a dashed line) on the trough reflector 298 and two straight dashed lines from the sides of the trough reflector 298 to the point on the focal line 211. A longitudinal plane 161 is delineated between a straight dashed line along the reflector trough 298 and the focal line 211 and two end dashed lines to form a square. Because the sun's light is only focused in one dimension, the light concentration at the focus line 211 is relatively low. Considering current engineering limitations, a concentration factor on the order of ˜100 times of normal sun luminance is achievable.

### SUMMARY OF THE INVENTION

The present invention provides a solar reflector operable to achieve higher solar concentration in a trough reflector focus device. The present invention further provides a device for providing additional focal points in the longitudinal direction. A plurality of solar reflectors provide a plurality of focal points instead of a focus line. At the focal points, many times higher concentrations of light are provided than in the focus line. In one application, a photovoltaic cell is placed at the focal point to generate electricity from solar energy for higher current per unit area of solar cell. In another application, a heat absorber is placed at the focal point to achieve higher temperatures.

In accordance with one aspect of the invention, a device for adding focus in the longitudinal direction of a parabolic trough reflector includes a focusing device disposed on a focal line of the parabolic trough reflector, the focusing device forming a longitudinal focal point with high light intensity in overlapping relationship to a transverse focus point provided by the trough reflector.

In accordance with another aspect of the invention, a device for adding focus in the longitudinal direction of a parabolic trough reflector includes a linear array of focusing devices disposed on a focal line of the parabolic trough reflector, the focusing devices forming longitudinal focal points in overlapping relationship to respective transverse focus points provided by the trough reflector.

In accordance with another aspect of the invention, a mobile computing device having interchangeable modules includes a base module, a programmable function module mechanically and electrically coupled to the base module, and a display module mechanically and electrically coupled to the programmable function module and mechanically coupled to the base module.

There has been outlined, rather broadly, the more important features of the invention in order that the detailed description thereof that follows may be better understood, and in order that the present contribution to the art may be better appreciated. There are, of course, additional features of the invention that will be described below and which will form the subject matter of the claims appended herein.

In this respect, before explaining at least one embodiment of the invention in detail, it is to be understood that the invention is not limited in its application to the details of design and to the arrangement of the components set forth in the following description or illustrated in the drawings. The invention is capable of other embodiments and of being practiced and carried out in various ways. Also, it is to be understood that the phraseology and terminology employed herein, as well as the abstract, are for the purpose of description and should not be regarded as limiting. As such, those skilled in the art will appreciate that the conception upon which this disclosure is based may readily be utilized as a basis for the designing of other methods and systems for carrying out the several purposes of the present invention. It is important, therefore, that the claims be regarded as including such equivalent methods and systems insofar as they do not depart from the spirit and scope of the present invention.

### BRIEF DESCRIPTION OF THE DRAWINGS

The present disclosure may be better understood and its numerous features and advantages made apparent to those skilled in the art by referencing the accompanying drawings wherein:

FIG. 1 is a schematic representation of a parabolic trough reflector having a solar receiver in accordance with the invention;

FIG. 2 is a schematic representation of a prior art parabolic trough reflector;

FIG. 3A is a schematic representation of a lens in a parabolic plane in accordance with the invention;

FIG. 3B is a schematic representation of the lens of FIG. 3A in a longitudinal plane in accordance with the invention;

FIG. 4 is a schematic representation of an alternative Fresnel lens in accordance with the invention;

FIG. 5A is a schematic representation of a focusing mirror in the parabolic plane in accordance with the invention

FIG. 5B is a schematic representation of the focusing mirror of FIG. 5A in the longitudinal plane in accordance with the invention;

FIG. 6A is a perspective view of a solar receiver in accordance with the invention;

FIG. 6B is a side elevation view of the solar receiver of FIG. 6A;

FIG. 6C is an end elevation view of the solar receiver of FIG. 6A;

FIG. 7 is a schematic representation of a solar receiver mounted on a support structure in accordance with the invention;

FIG. 8 is a schematic representation of a plurality of solar receivers disposed at a tilt direction on a structure in accordance with the invention;

FIG. 9 is a schematic representation of an alternative plurality of solar receivers disposed at a tilt direction on a structure in accordance with the invention;

FIG. 10A is a schematic representation of a focal line;

FIG. 10B is a schematic representation of a plurality of focal points in accordance with the invention;

FIG. 10C is a schematic representation of an alternative plurality of focal points in accordance with the invention;

FIG. 11A is a schematic representation of a hyperbolic mirror in the parabolic plane in accordance with the invention;

FIG. 11B is a schematic representation of the hyperbolic mirror of FIG. 11A in the longitudinal plane in accordance with the invention;

FIG. 11C is a schematic representation of contour lines of the hyperbolic mirror of FIG. 11A;

FIG. 12A is a schematic representation of a solar receiver housed inside of a box in accordance with the invention

FIG. 12B is a schematic representation of the solar receiver of FIG. 12A showing grooved wheels engaged with rails in accordance with the invention;

FIG. 13A is a schematic representation of a boxcar in accordance with the invention;

FIG. 13B is a schematic representation of an inside of the boxcar of FIG. 13A;

FIG. 14A is a schematic representation of a boxcar housing a plurality of solar receivers in accordance with the invention;

FIG. 14B is a schematic representation of a boxcar housing a plurality of solar receivers having a different tilt angle than those shown in FIG. 14A;

FIGS. 15A and 15B are schematic representations showing translation of a train of solar receiver boxcars on a trough reflector structure in accordance with the invention; and

FIG. 16 is a schematic representation of a connection between two solar receiver boxcars in accordance with the invention.

### DETAILED DESCRIPTION OF THE INVENTION

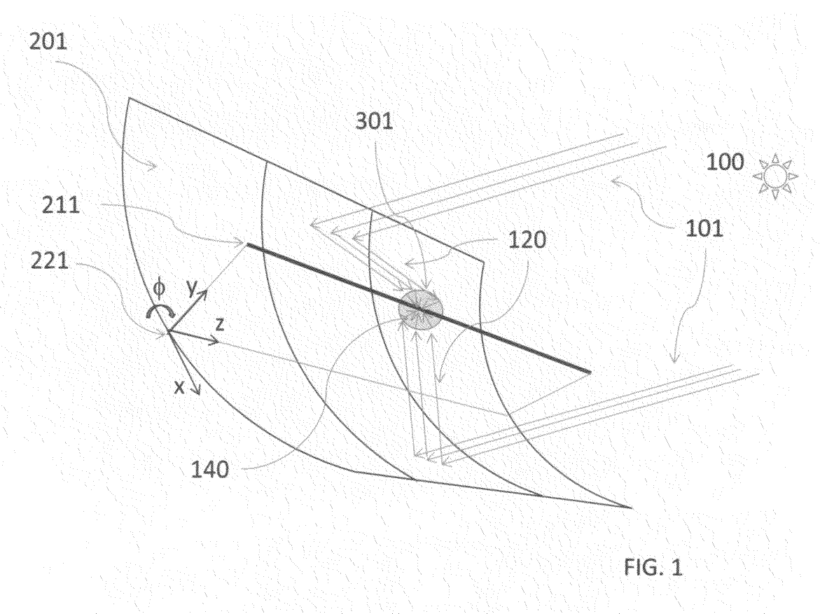

FIG. 1 illustrates a solar receiver 301 located at a focal line 211 of a parabolic trough reflector 201. The solar receiver 301 is operable to focus a section of the light of the focal line 211 onto a focal point 140. The sun 100 shines parallel light rays 101 onto the parabolic trough reflector 201. When the parabolic trough reflector 201 faces to the sun 100, the reflected light 120 is focused onto the focal line 211. The solar receiver 301 in accordance with the invention is placed at the focal line 211 to intersect a section of the reflected light 120 and focus the reflected light 120 onto the focal point 140.

A Cartesian coordinate system 221 is drawn on the parabolic trough reflector 201 to indicate axis and directions with the origin disposed at the vertex of the parabolic trough reflector 201. The parabolic trough reflector 201 rotates along the z-axis or a line parallel to the z-axis to track the sun 100 as it moves across the sky. The reflected light 120 is normally focused on the focal line 211 above the vertex of the parabolic trough reflector 210. During tracking, the sun 100 is always in the yz plane, also known as the longitudinal plane. In the xy plane, also known as transverse plane or parabolic plane, reflected light 120 is focused into a point. In the yz plane, reflected light 120 is unfocused before reaching the solar receiver 301. The solar receiver 301 focuses the reflected light 120 in the yz plane into the focal point 140 that overlaps the focal point in the xy plane. Because the solar receiver 301 is relatively small, it only intersects a section of the light along the z axis, and locally the light is focused into one point within the solar receiver 301. The focused light has a higher concentrated light than just in a line. The present invention thus allows the placement of a solar voltaic cell at the focal point 140 to receive a highly concentrated solar luminance.

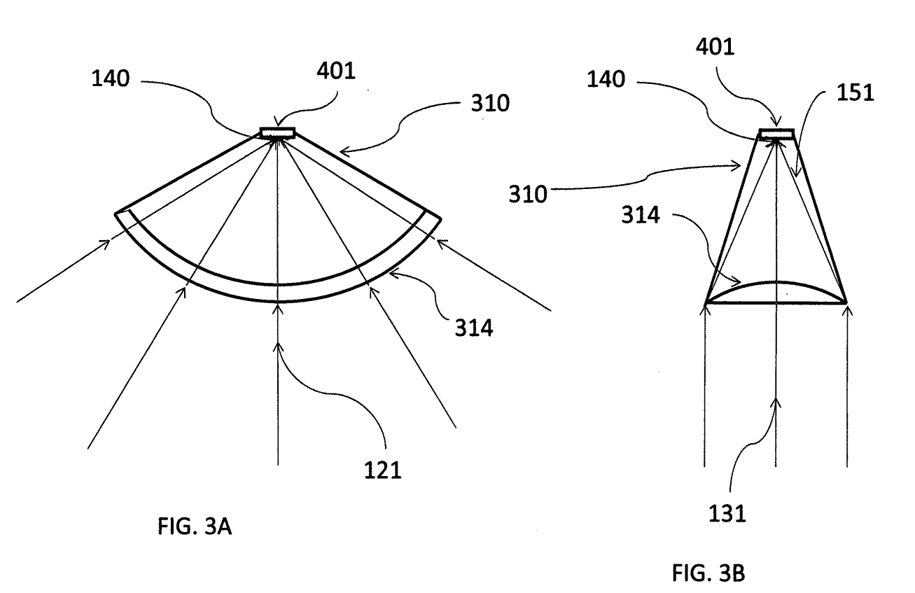

FIGS. 3A and 3B illustrate a lens 310 of the solar receiver 301 that focuses reflected light onto the focal point 140. FIG. 3A shows the lens 310 in the parabolic plane 162 and shows light rays 121 focused onto a focal point 140. The lens 310 comprises a belt shaped cylindrical lens 314 that has little or no focusing power in the parabolic plane 162 to change the light path and leaves the light focused on the focal point 140. FIG, 3B shows a reflected parallel light beam 131 in the longitudinal plane 161. A section of the parallel light beam 131 is focused into a cone 151 by the cylindrical lens 314 and onto the focal point 140. A photovoltaic cell 401 is shown disposed at the focal point 140.

The belt shape cylindrical lens 314 is different from a conventional cylindrical lens which is flat along the longitudinal direction. A conventional cylindrical lens, when intersected with radial focused light 121 would not focus the light into a single spot in this situation. The cylindrical lens 314 is curved in a round or nearly round belt shape so that the focal points overlap together in all directions.

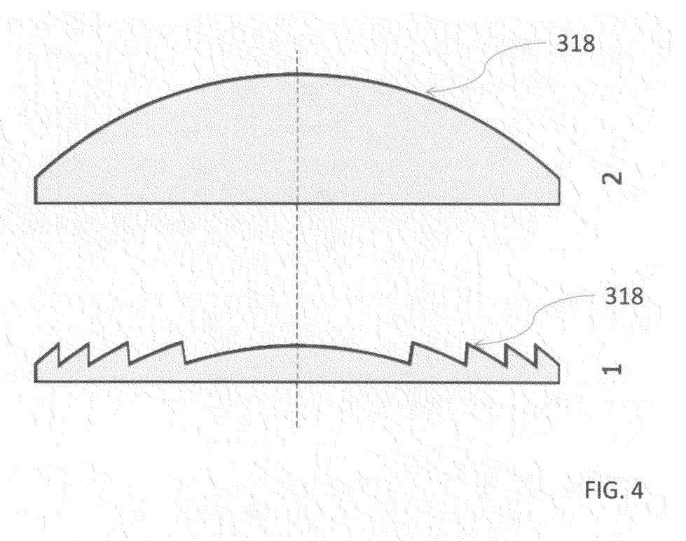

FIG. 4 illustrates an alternative cylindrical lens including a Fresnel lens 318. In the lens cross section, the Fresnel lens 318 has the same focal power as a circular surfaced lens 314. In accordance with the invention, a cylindrical Fresnel lens can be used in place of cylindrical lens 310 (FIG. 3).

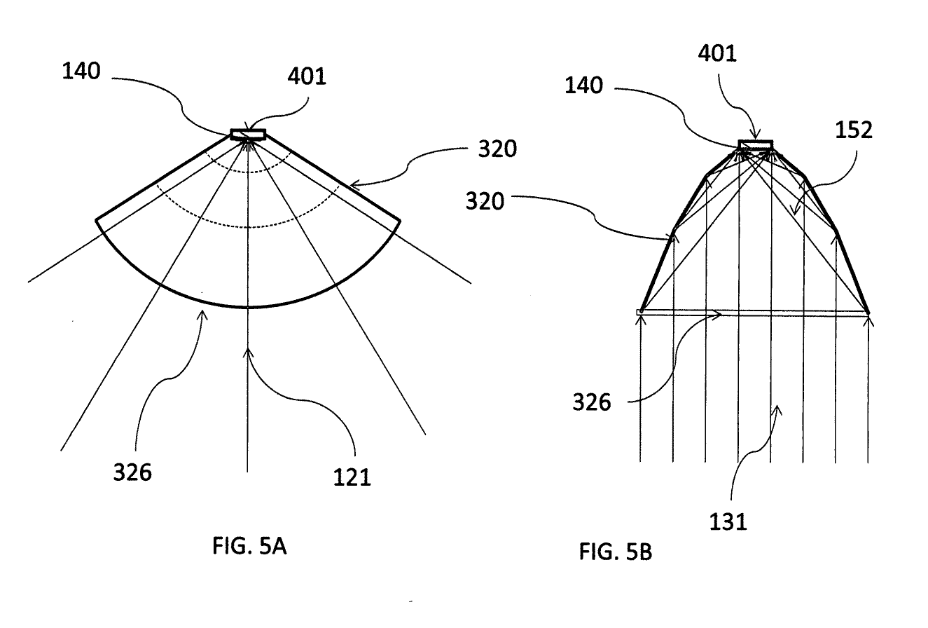

FIGS. 5A and 5B illustrate a longitudinal focusing mirror device 326 in a solar receiver 320. The device 326 focuses light in the parabolic focus plane 162 and further focuses parallel light in a longitudinal plane 161 onto the focus point 140. FIG. 5A shows the solar receiver 320 in the parabolic focus plane 162. The light reflected from the trough reflector parabolic surface is focused on the focal point 140 unchanged through the receiver 320. The receiver 320 is made of two open shells of reflectors which do not change light within the plane 162. With reference to FIG. 5B, the solar receiver 320 includes two half parabolic mirrors that reflect parallel light 131 onto the focal point 140. The focal point 140 may be at the center of the solar voltaic cell 401. The longitudinal focusing mirror device 326 can be described as a parabolic trough being bent into a curved shape with the vertex line squeezed into one point in the parabolic focus plane 162. The opening forms an arc. In the longitudinal plane 161, the mirror has a parabolic shape.

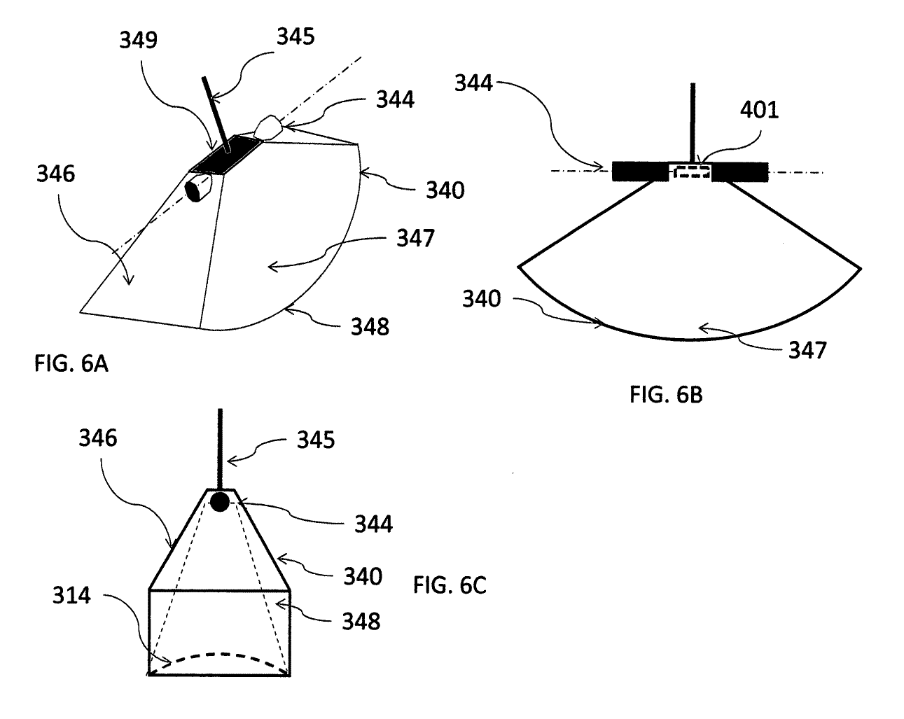

FIGS. 6A, 6B and 6C illustrate perspective, side elevation and end elevation views of a solar receiver 340 in accordance with the invention. The solar receiver 340 includes a longitudinal focus device solar cell 401 (FIG. 6B). With reference to FIG. 6A, the solar receiver 340 comprises two arc surfaces 347 at ends thereof, two trapezoidal surfaces 346 on sides thereof, one small square surface 349 on the top thereof, and one belt surface 348 on the bottom thereof. An axis 344 has each end structured on the trapezoidal surfaces 346. A linkage 345 is made on the surface 349, which is used to drive a tilt motion around the axis 344. With reference to FIG. 6B, the arc surface 347 is shown with an axis in plane. The solar voltaic cell 401 is shown disposed at the focal point 140. FIG. 6C shows the axis 344 as a round rod, curved up belt surface 348 as a rectangle on the bottom, and tilted trapezoidal side 346 in the middle. The dashed line highlights a cross section of cylindrical lens and also the arc surface 347 in the middle.

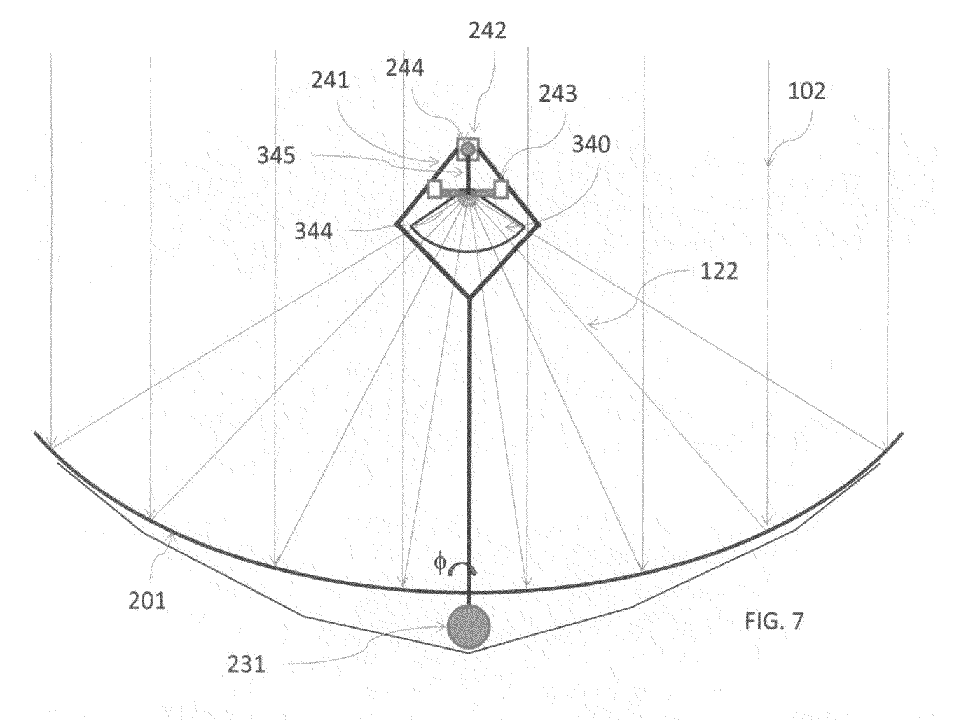

FIG. 7 illustrates the solar receiver 340 with a longitudinal focus device placed on a structure 241 at the focal point 140 of the parabolic trough reflector 201. The structure 241 is fixed on a parabolic mirror frame 231 behind the reflector 201 as a support of solar receiver 340. The structure 241 has two support beams 243. The support beams 243 hold the rotating axis 344 of the solar receiver 340. Another support 242 holds a translating bar 244. The translating bar 244 is linked to a tilting linkage 345 of the solar receiver 340. The parallel sun light 102 is reflected into focused light 122 into the solar receiver 340.

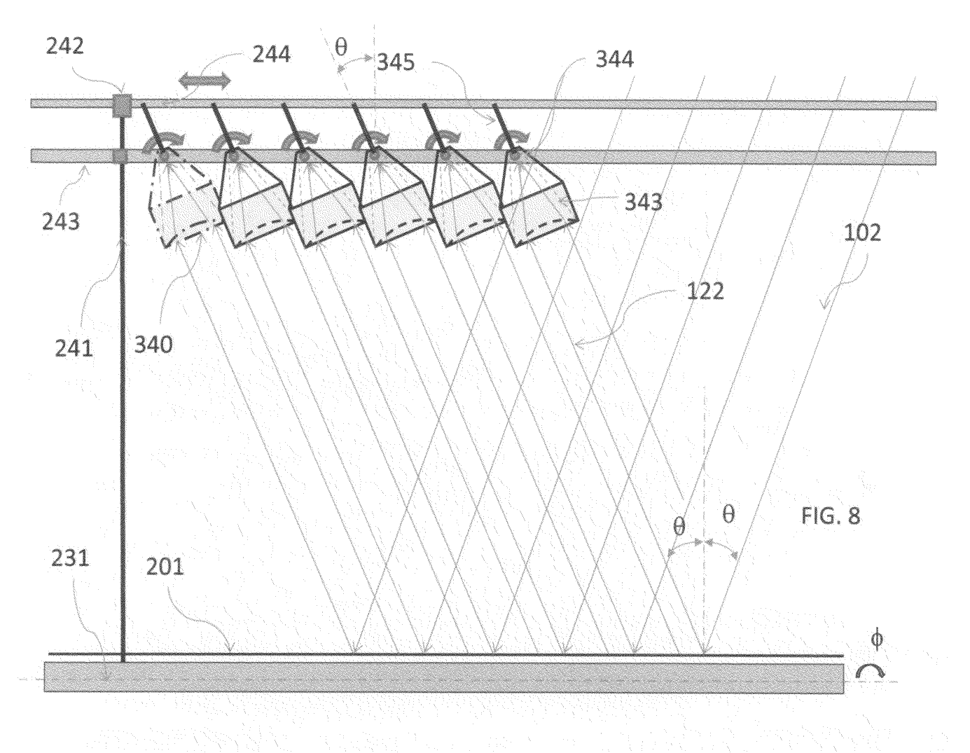

FIG. 8 illustrates a plurality of longitudinal focus solar receivers 340 placed at a tilt direction on a structure 243 by holding their axis. The tilt is provided by a driving translating bar 244 which is linked to the solar receivers 340 via linkages 345 at controlled positions. The translating bar 244 is supported by support 242 on the structure 241. The structure 241 is supported by the trough rotating frame 231 behind the reflector 201. Sun light 102 shines on the mirror with an angle θ and is reflected into parallel light 122 also with angle of θ from normal. The focus receivers 340 are tilted by an angle θ to face the reflected parallel light in order to focus the light 343 onto respective focal points. The plurality of solar receivers 340 are placed next to each other in order to collect all of the light.

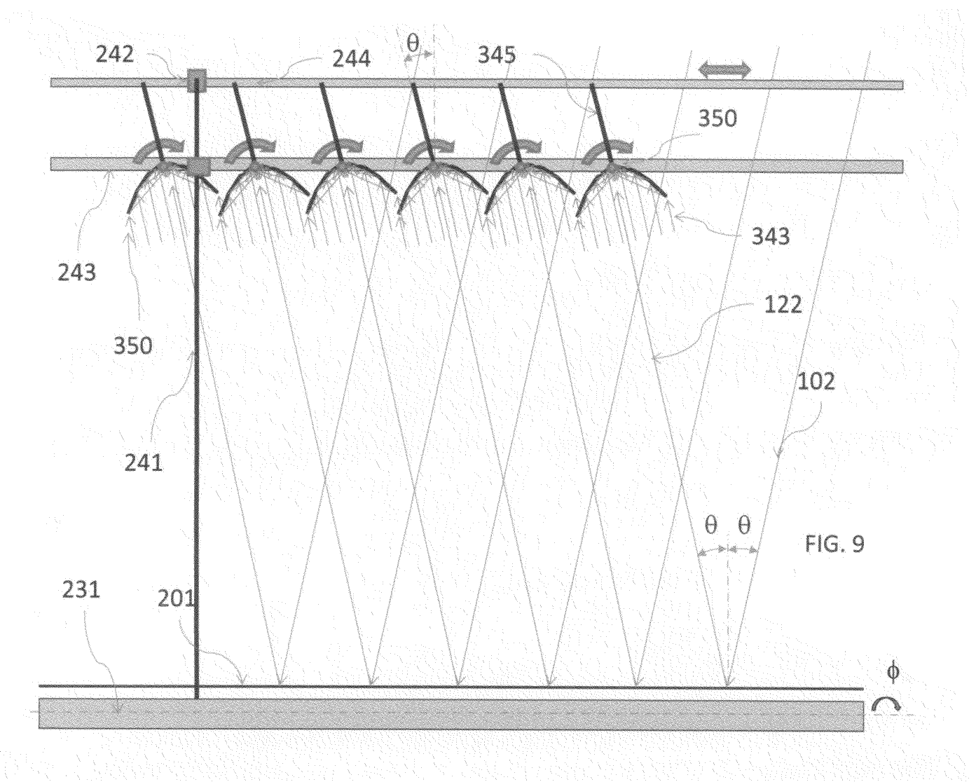

FIG. 9 illustrates a plurality of solar receivers 350 with mirror focusing devices placed at a tilt direction on the structure 243 by holding their axis. The solar receivers 350 are similar to solar receivers 340 but use mirrors instead of lenses. The tilt is provided by the driving translating bar 244 which is linked to the solar receivers 350 via linkages 345 at controlled positions. The translating bar 244 is supported by support 242 on the structure 241. The structure 241 is supported by the trough rotating frame 231 behind reflector 201. Sun light 102 shines onto the mirror with an angle θ and is reflected into parallel light 122 also with angle θ from normal. The solar receivers 350 are tilted by an angle θ to face the reflected parallel light in order to focus the light 343 onto respective focal points. The solar receivers 350 are placed next to each other in order to collect all the light from the trough reflector.

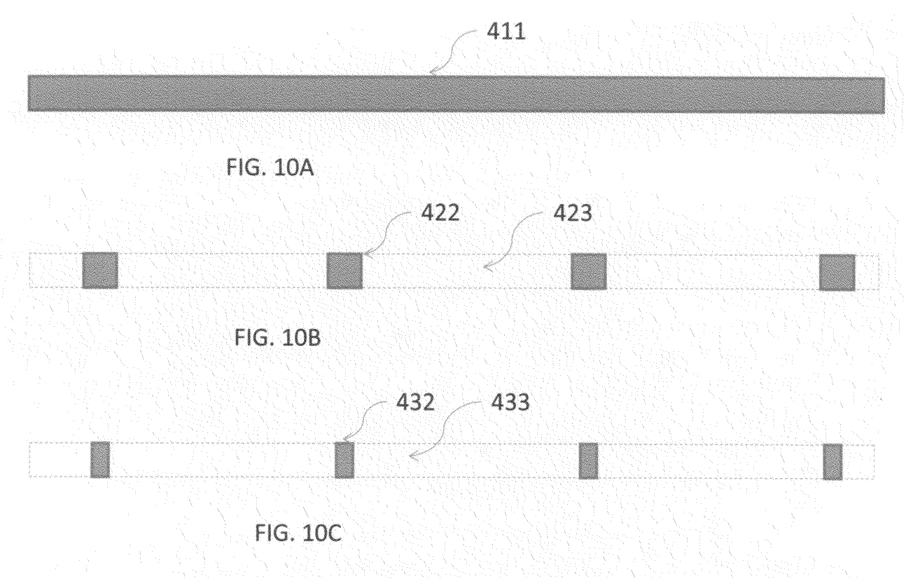

FIG. 10A illustrates a focal line 411 while FIGS. 10B and 10C illustrate focal points provided by the solar receivers in accordance with the invention. Focal line 411 is produced by a parabolic trough reflector. The parabolic trough reflector forms a strip along the axis instead of a true line due to engineering limitations. Focal points 422 and 432 are provided by concentrating light in the regions 423 and 433 respectively of the strip 411. Focus points are more concentrated than the strip. With reference to FIG. 10B, a plurality of near-square focal points 422 are provided by additional belt cylindrical lenses or squeezed parabolic mirrors. By adjusting the focus of the solar receivers, a sharper focal point 432 can be achieved as shown in FIG. 10C.

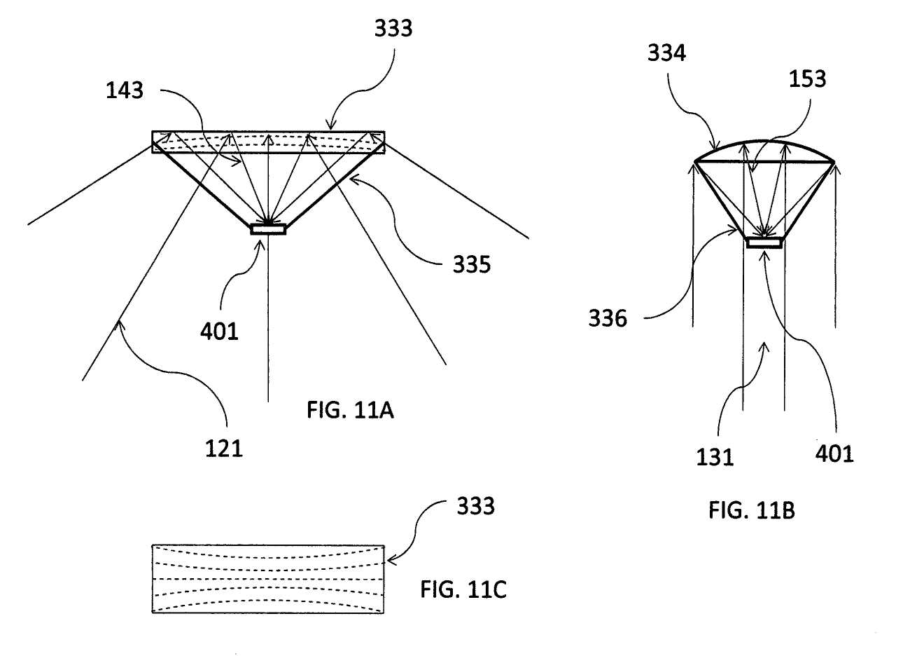

FIGS. 11A, 11B, and 11C illustrate an alternative way of focusing light in the longitudinal direction by reflecting it back to the center. FIG. 11A shows a hyperbolic mirror 333 reflecting focused light 121 into focused light 143 and onto the solar voltaic cell 401 in the parabolic focal plane 162. FIG. 11B shows a hyperbolic surface 334 focusing the parallel beams 131 into focused light 153 at the solar voltaic cell 401. Windows 335 and 336 allow entry of light and also provide support to connect the solar reflector to the solar voltaic cell 401. FIG. 11C shows contour lines of the hyperbolic mirror 333.

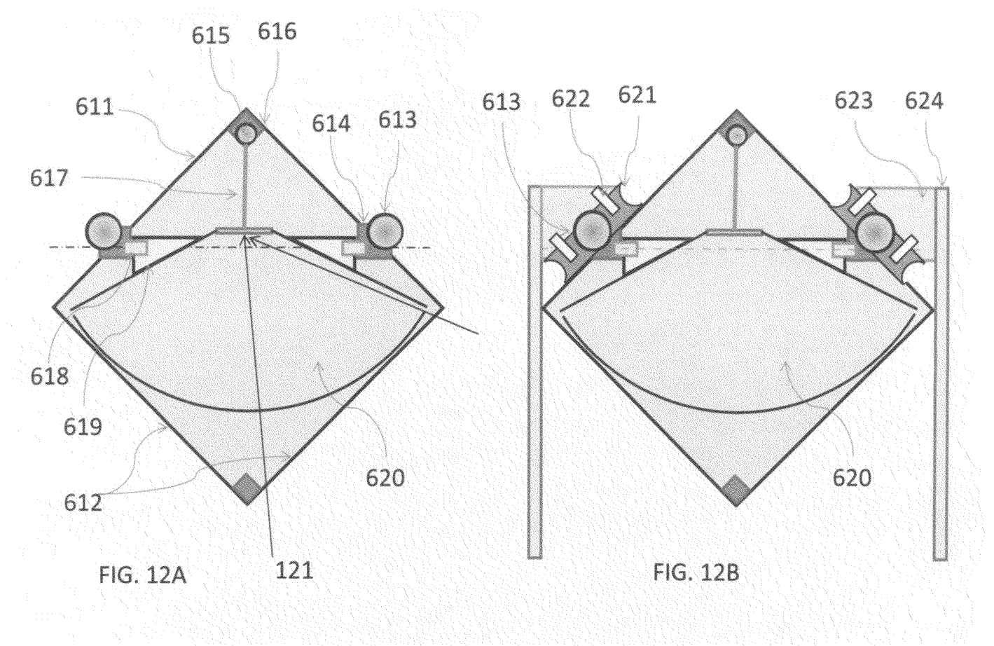

FIGS. 12A and 12B illustrate a solar receiver 620 with a longitudinal focus device housed inside a box 611. FIG. 12A shows the cross section of the box 611 as a four sided tilted square or diamond shape, although the cross section of the box 611 is not limited to the shown shape. The bottom two sides are flat glass windows 612 to allow entry of reflected light 121 from the parabolic trough reflector. Four edges of the glass windows 612 are sealed against a box frame to form an air tight enclosure to protect optics and solar cells from environmental damages. The surfaces of the windows 612 are also coated with anti-reflection films to enhance light transmission. The other two sides of the box 611 are made of structural materials, such as metal or plastic, to support the whole box as a rigid and solid structure. Inside the box 611, two supporting beams 614 are attached to top surfaces of the box 611 along the longitudinal direction. Shaft holes are made in the supporting beams 614 to support an axis 618 of the solar receiver 620. On the other end, a base 619 of the solar receiver 620 also has a shaft hole to support the axis 618. The base 619 is a structural base of the solar receiver 620 to hold focusing device, solar voltaic cell, and a linkage 617 for driving the receiver tilt around the axis 618. On the top corner of the box 611, a driving rod 615 is supported by a holder 616. The motion of driving rod 615 tilts the solar receiver 620 around its axis 618. The solar receiver 620 can be made of a parabolic mirror, a belt shaped cylindrical lens, or a hyperbolic surface as described above. Outside of the box 611, two rails 613 are mounted on the roof of the box 611 along the longitudinal direction. The two parallel rails 613 are mounted to the box 611 in order to support longitudinal motion of the box 611. As illustrated in FIG. 12B, a pair of grooved wheels engage with rails 613 to only allow longitudinal translation motion. The grooved wheels 621 are connected to supporting frames 623 and 624 via axis 622 as a part of the supporting frame. The supporting frame 624 is further joined to the trough supporting frame as described above. The box 611 is referred to as a boxcar because of the arrangement of the wheels on the rails.

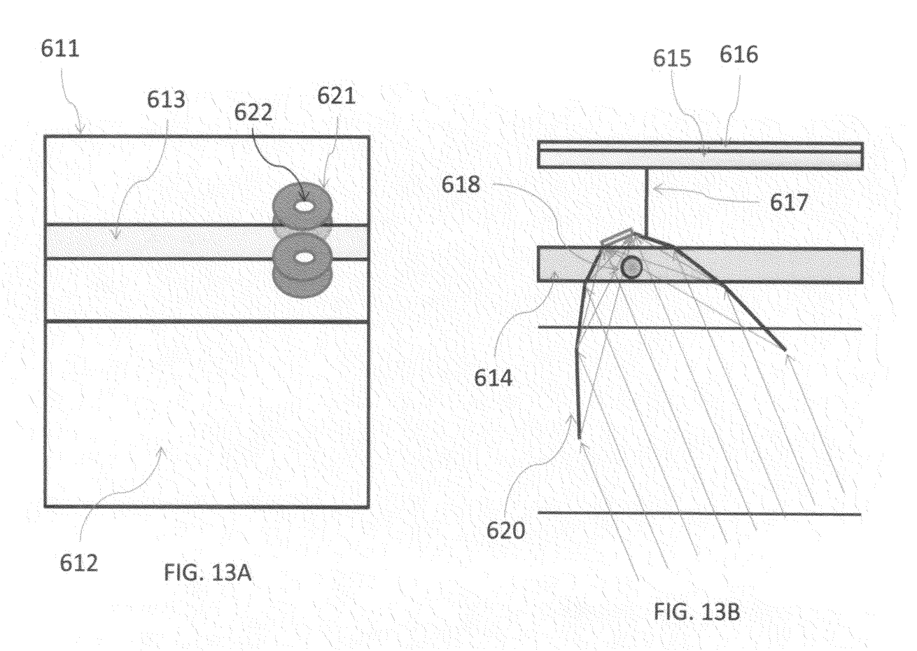

FIGS. 13A and 13B illustrate side views of the boxcar 611. With reference to FIG. 13A, the outside of the boxcar 611 comprises a supporting structure on the roof and windows 612 on the bottom. On the roof, a rail 613 is laid along the box roof and engaged with a pair of wheels 621 from the supporting frame. FIG. 13B shows the inside of the boxcar 611 with a solar receiver 620 in a tilted position. The solar receiver 620 is held up by the axis 618 on internal supporting beams 614. The tilt position is controlled by a linkage 617 via driving rod 615 which is supported via a beam 616.

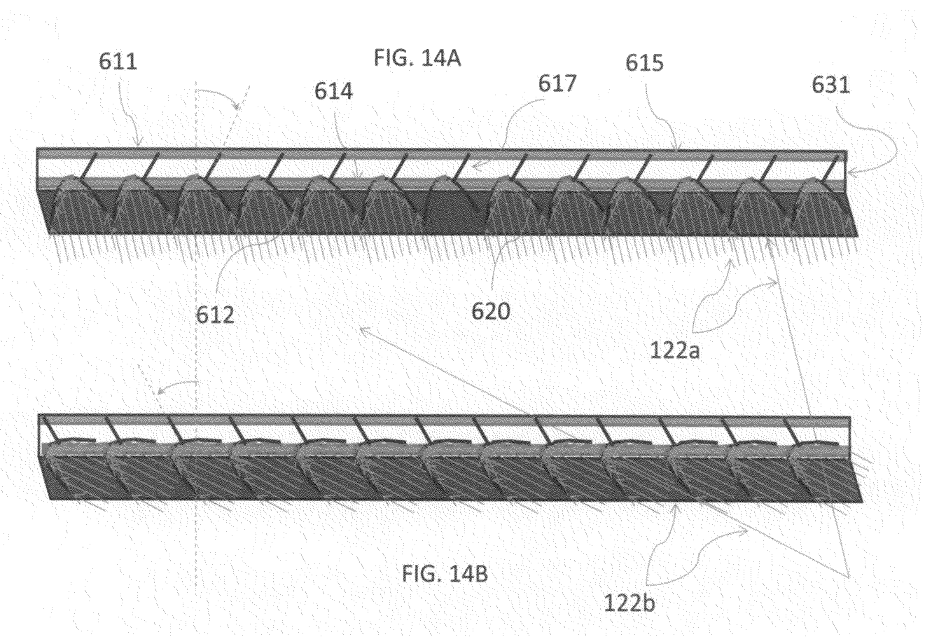

FIGS. 14A and 14B illustrate a complete boxcar 611 housing a plurality of solar receivers 620. FIG. 14A shows the plurality of solar receivers 620 are all tilted at the same angle toward the reflected light 122a in a case where the reflected light is close to normal. The boxcar 611 comprises two sides on top as a supporting structure, two sides at the bottom as windows 612, and two ends 631 as connections to other boxcars. On the top, each solar receiver 620 is shown connected to a supporting beam 614, and a tilt driving rod 615 via linkage 617. Two beams 614 support the plurality of solar receivers 620 and one driving rod drives all of the solar receivers 620 to the same tilt. FIG. 14B shows the plurality of solar receivers 620 tilted at another angle to face reflected light 122b in the case where the reflected light is far off normal. One skilled in the art will recognize that the boxcar 611 may house any number of solar receivers 620.

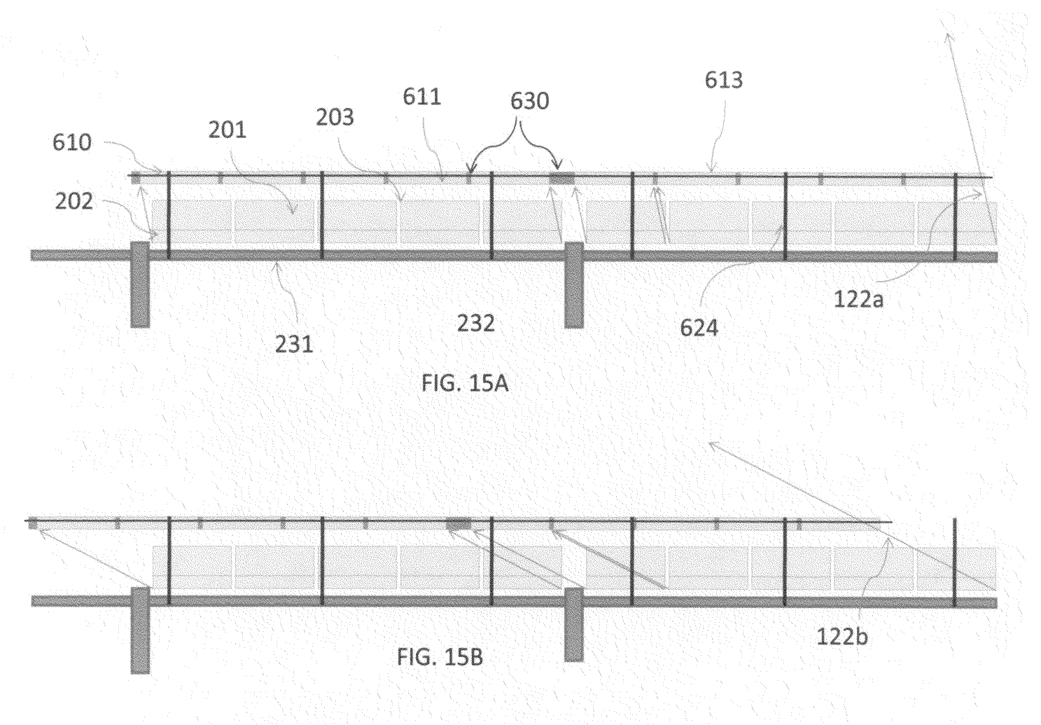

FIGS. 15A and 15B illustrate the translation of a train of solar receiver boxcars on a trough reflector structure. FIG. 15A shows a train 610 of solar receiver boxcars 611 above the trough reflector structure 231. The train 610 of solar receiver boxcars 611 mounted with rails 613 are supported by wheels on support 624. The train 610 is translated in the longitudinal direction to match the reflection pattern from the trough mirror. Each boxcar 611 has the same length as a trough mirror 201 and each connection part 630 also has the same gap 203. The reflected light 122a illustrates the shift from mirror 202 to receiver train 610. FIG. 15A shows the case of near normal reflection from the trough while FIG. 15B shows the case of far off normal reflection. The difference between the two figures illustrates the receiver train moving from right to left. The train of receivers described above is not limited to solar receivers only. The train of receivers can also be comprised of regular flat photovoltaic cells without focusing devices.

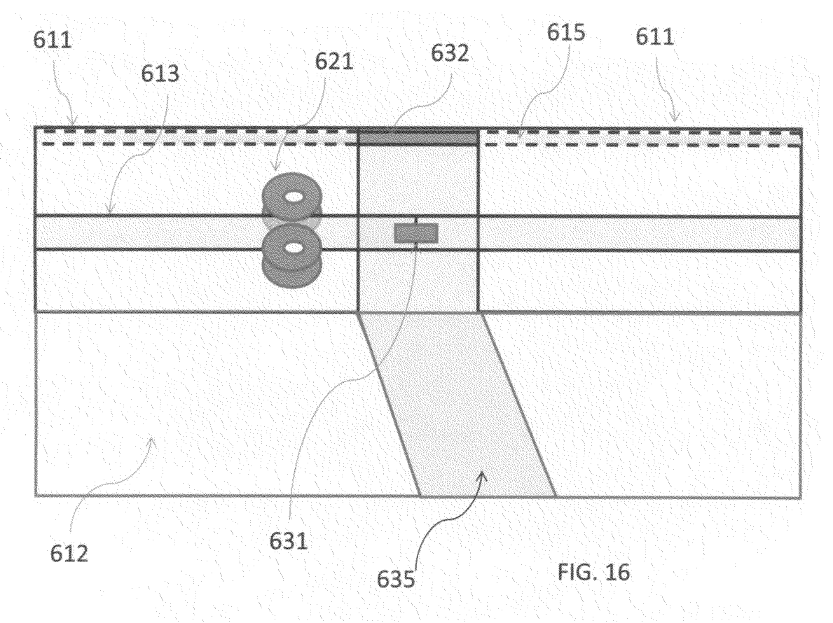

FIG. 16 illustrates the connection between two solar receiver boxcars 611. The connection part 635 connects structures of the two boxcars 611 together. In addition, a connection pin 631 holds rails 613 from two sides together to allow the wheels 621 to run through the connection smoothly. Also connection rod 632 joins the tilt driving rod 615 (shown in dashed lines) from left to right together. As a result, the driving motion is translated from one box to another.

The present invention provides a solar reflector operable to achieve higher solar concentration in a trough reflector focus device. The present invention further provides a device for providing additional focal points in the longitudinal direction. A plurality of solar reflectors provide a plurality of focal points instead of a focus line. At the focal points, many times higher concentrations of light are provided than in the focus line. In one application, a photovoltaic cell is placed at the focal point to generate electricity from solar energy for higher current per unit area of solar cell. In another application, a heat absorber is placed at the focal point to achieve higher temperatures.

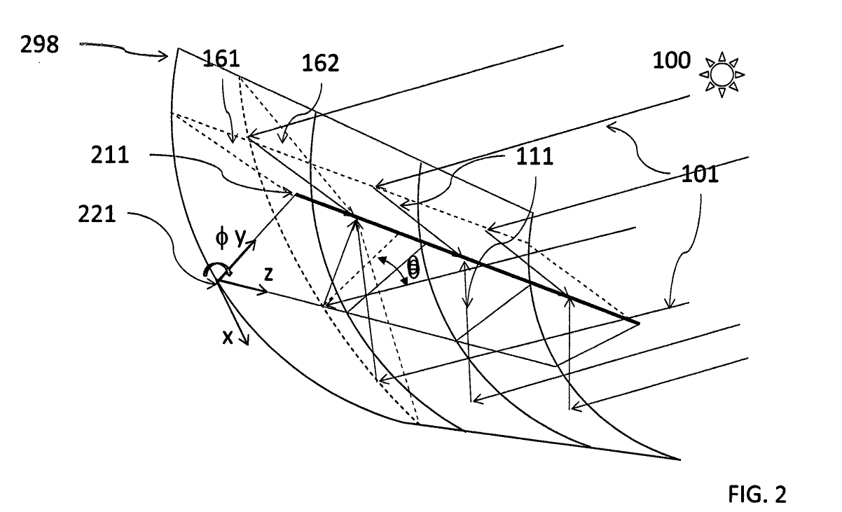

A trough reflector is rotated around the longitudinal axis through an angle φ to track the sun and to focus reflected light into a focal line. Despite of line focusing, as shown in FIGS. 1 and 2, reflected light in the longitudinal plane shows in parallel with an angle θ from normal direction. The angle θ varies during the tracking at different times of the day in the year. The device of the invention tracks the variation of the angle θ to provide a consistent focal point. Two examples of tracking angle θ have been illustrated in FIGS. 8 and 9. The solar receivers with longitudinal focus devices are tilted with an angle θ by a control to face the parallel beam and focus the light beam on one focal point. A string of solar receivers with longitudinal focus devices are controlled simultaneously in the same degree of angle θ. In the tracking operation, a solar trough concentrator is controlled in φand θ angles to have light always focused on the focal point. The rotation of the trough reflector through angle φ carries the trough mirror and solar receivers with longitudinal focus located at focal line through firm frame structures. The tilt angle θ of the solar receivers is controlled simultaneously by a translating bar in the longitudinal direction. In such a position, the reflected light is received at the focal line by tilted solar receivers to form a focal point. The translation drives each receiver to tilt around the axis which crosses the focal line of the trough reflector. The tilt of the solar receivers can be provided by other kinds of mechanical driving mechanisms, such as gears and rotating shafts, or other known arts.

In one application, a solar voltaic cell is disposed at the focal point to generate electricity from the received concentrated light. At the tilt angle θ, the solar receiver with a longitudinal focus device inside focuses a section of light onto the focal point on the solar voltaic cell where the trough focal line crosses the tilt axis. In operation, φ and θ are controlled according to the time of the day in the year to have sun light focused on the solar voltaic cell.

The longitudinal focus device inside the solar receiver is a device that focuses the reflected light from the trough reflector onto a focal point rather than onto the focal line. In one aspect of the invention, the longitudinal focus device only has focusing power in the longitudinal direction but not in the transverse direction where light is already focused by the trough reflector. The lens of FIGS. 3A and 3B focuses the parallel light in the longitudinal plane but leaves focused light in transverse plane unchanged. The cylindrical lens is curved up in a belt shape in the transverse plane where it has no focusing power. The cylindrical lens focuses the parallel light in the longitudinal plane onto a focal point which overlaps with the trough reflector focus. In this art, it is very important to design the focal length of the lens to match the relative position of the lens from the trough reflector focal line in order to overlap the two focal points in cross planes. The cylindrical lens is not limited to plano-convex but may also include any type of lens with a positive focal length. In practice, the cylindrical lens can be replaced by a cylindrical Fresnel lens as shown in FIGS. 4A and 4B. The belt curve shown in FIG. 3A is illustrated as a circle with a radius equal to the focal length of the cylindrical lens.

In accordance with another aspect of the invention and with reference to FIGS. 5A and 5B, the lens focuses the parallel light in the longitudinal plane but leaves focused light in the transverse plane unchanged. In the longitudinal plane, FIG. 5B shows the focus device as a parabolic mirror that reflects parallel light onto the focal point. In the transverse plane, the mirror stretches out as a circular arc that has its center at the focal point. The mirror has a gradient in its radial direction and circular contour lines. Since the focused light from trough reflector is along the radial direction of the mirror, the mirror in the solar receiver only bounces light out of the plane of the paper in FIG. 5A and focuses light in the longitudinal plane in FIG. 5B. The mirrors look like open shells and each inner surface is coated as an optical mirror which reflects the full spectrum of solar light. In a radial cross section view of the shell, the mirror surface has a parabolic shape. The mirrors can alternatively start as a trough surface and then bend into an arc in its longitudinal plane by squeezing the trough bottom into a point. Such a defined surface focuses trough reflected light into a point instead of a line. The mirrors perform the same function to enhance luminance of solar light at focus points for higher concentration of solar light.

Another alternative point focus device includes a hyperbolic reflective mirror to focus the light backward in the direction of the trough reflector. In accordance with this aspect of the invention, the mirror focuses the parallel beam in the longitudinal plane onto the focal point. In the transverse plane, the mirror reflects already focused light from the trough reflector onto the same focal point as in the longitudinal plane.

Advantages are provided by packing a plurality of solar receivers in a box for field applications. The box provides for protection of photo voltaic cells and optics in the solar receivers. The box also provides for simplicity of operation, reliability and saves materials. In a sealed box, a plurality of solar receivers are placed in a row to face toward the reflected light from the trough reflector. Inside the box, a number of solar receivers hang on two beams in the longitudinal direction via an axis each. Each solar receiver is also connected to the tilt driving rod via the linkage. The motion of the driving rod tilts all solar receivers simultaneously by the same angle. The two roof sides of the box and the two beams as well as the tilt driving rod holder form a rigid structural support for the box. The windows are the two bottom sides of the box that allow solar light therethrough without loss. The windows provide open, clear aperture for the reflected light from the trough reflector. The windows also have an anti-reflective coating to reduce loss. The two end plates provide structural support for rigidity and sealing. The driving rod goes through the end plates for connection and retains the air-tightness of the box. The box is sealed at all edges for air-tightness to protect the solar receivers from environmental harm. This method of packaging the solar receivers provides ease of transportation and installation as well as long lasting operation.

The solar receivers are illustrated as parabolic mirrors in FIGS. 12A, 12B, 13A, 13B, 14A and 14B but may have other configurations. Motion of the solar receivers has been described as tilt but other motions are not excluded. Thus a belt shaped lens at a fixed tilt may be used. A row of such lenses joined together could serve as a window. Through a row of lenses, reflected light from the trough reflector focuses onto a row of focal points along the trough focal line. As the direction of the sun light tilt e varies, the focal points move along the focal line. In this particular case, the driving rod would drive a linear translation of solar receivers to catch the focal points. The window can be replaced by a single piece of curved window. The curved window provides no obstacles to the solar receiver motion and no blockage of reflected light from the trough reflector.

The solar receiver boxes are connected to the supporting frame via rails and wheels. Such a scheme allows the solar receiver boxcars to move along the focal axis of the trough reflector. The rail may be mounted on the boxcar and wheels mounted on the supporting frame. In principle, one can reverse the respective mountings to provide the same function. Connection between two boxcars is provided for joining two boxcars together structurally. The connection also connects the rails and driving rod together to propagate the driving motion from one to the next. As a result, a series of boxcars provide a train. A train of solar receiver boxcars may move from right to left as sun light tilts away from the normal direction of the trough reflector. In this particular case, the solar receiver train has the same gap pattern as the trough reflector. The pattern match gains more light collection by the solar receivers.

The translation of solar receivers along the focal line is not limited to receivers with focus devices inside. The solar receiver can also be a flat panel of solar voltaic cells. The solar receivers may be stationary. The solar receivers may have a low focal factor and may not need to move in a range of tilt.

The foregoing description of the embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

I claim:

1. A device for adding focus in the longitudinal direction of a parabolic trough reflector, the device comprising:
a focusing device disposed on a focal line of the parabolic trough reflector, the focusing device forming a longitudinal focal point with high light intensity in overlapping relationship to a transverse focus point provided by the trough reflector.

2. The device of claim 1, wherein the focusing device is a lens.

3. The device of claim 1, wherein the focusing device is a mirror.

4. The device of claim 1, further comprising a photovoltaic cell disposed at the focal point.

5. The device of claim 1, further comprising a thermal absorber disposed at the focal point.

6. The device of claim 1, further comprising a tilt mechanism for facing the focusing device toward light reflected by the trough reflector with a defined angle.

7. A device for adding focus in the longitudinal direction of a parabolic trough reflector, the device comprising:
a linear array of focusing devices disposed on a focal line of the parabolic trough reflector, the focusing devices forming longitudinal focal points in overlapping relationship to respective transverse focus points provided by the trough reflector.

8. The device of claim 7, wherein the focusing devices comprise lenses.

9. The device of claim 7, wherein the focusing devices comprise mirrors.

10. The device of claim 7, further comprising a photovoltaic cell disposed at the focal points.

11. The device of claim 7, further comprising a thermal absorber disposed at the focal points.

12. The device of claim 7, further comprising a control mechanism for tilting the plurality of focusing devices by the same angle.
